(19) United States
(12) Patent Application Publication
(10) Pub. No.: US 2005/0051857 A1
(43) Pub. Date: Mar. 10, 2005

(54) Semiconductor device

(75) Inventors: Takaaki Kawahara, Ibaraki (JP); Kazuyoshi Torii, Ibaraki (JP); Hiroshi Kitajima, Ibaraki-ken (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukaba-shi (JP)

(21) Appl. No.: 10/901,997

(22) Filed: Jul. 30, 2004

(30) Foreign Application Priority Data
Aug. 18, 2003 (JP) 2003-294264

(51) Int. Cl. H01L 29/76

(52) U.S. Cl. 257/411

(57) ABSTRACT

A semiconductor device of the present invention comprises: a silicon substrate; a gate insulating film on the silicon substrate; and a gate electrode on the gate insulating film, wherein the gate insulating film includes: a first insulating film; a second insulating film on the first insulating film; and a metal nitride film on the second insulating film. The metal nitride film may be either AlN or Hf₃N₄. The metal nitride film may include nitrides of two or more different metals.

### BACKGROUND OF THE INVENTION

1. Field of the Invention

The present invention relates to a semiconductor device, and more particularly to a semiconductor device which includes a silicon substrate, a gate insulating film formed on the silicon substrate, and a gate electrode formed on the gate insulating film.

2. Background Art

In recent years, the integration density of semiconductor integrated circuit devices has considerably increased. As such, devices such as transistors, etc. in MOS (Metal Oxide Semiconductor) semiconductor devices, for example, have been miniaturized and enhanced in performance. Especially, the gate insulating films, which are a component of the MOS structure, have become thinner and thinner to accommodate the miniaturization, higher-speed operation, and lower-voltage operation of the transistors.

Conventionally, the gate insulating films have been formed of an SiO₂ film (silicon oxide film). As the gate electrodes have been miniaturized, the thickness of the gate insulating films has been reduced. However, considerably reducing the thickness of a gate insulating film causes carriers (electrons and holes) to directly pass through the film, thereby increasing the tunneling current, or gate leakage current.

According to ITRS (International Technology Roadmap for Semiconductors) 2001, the 65 nm generation semiconductor devices, which will be available by 2007, require gate insulating films having an equivalent oxide thickness of 1.2 nm-1.6 nm. However, when an SiO₂ film is used as a gate insulating film, the gate leakage current due to the tunneling current exceeds the maximum permissible value, requiring a new material to be employed instead of the SiO₂ film.

Research efforts have been made to use materials having a higher dielectric constant than SiO₂ films for gate insulating films. Such high dielectric constant films (hereinafter referred to as High-k films) are electrically thin but physically thick and exhibit a small leakage current.

Incidentally, various heat treatments are carried out in a semiconductor device manufacturing process. An example is activation annealing performed after ion implantation. Such a heat treatment, however, causes reactions, such as formation of silicide, at the interface between the High-k film and the gate electrode formed on it. Furthermore, there is another problem in that impurities in the gate electrode (e.g., boron (B) in the case of a PMOS device) diffuse into the silicon substrate through the High-k film due to heat. Still another problem is that the absolute value of the PMOS threshold voltage (Vth) increases, resulting in increased power consumption. This contradicts the fact that High-k films have been developed for use in miniaturized transistors operating at a low voltage.

To overcome the above problems, it is proposed that an SiN film (silicon nitride film) having a film thickness of 5 Å may be formed between an HfO₂ film (High-k film) and a polysilicon film (gate electrode). See Y. Morisaki et al., “Ultra-thin (T_{eff}^{inv}=1.7 nm) Poly-Si-gated SiN/HfO₂/SiON High-k Stack Dielectrics with High Thermal Stability (1,150° C.)”, IEDM (International Electron Devices Meeting), 2002 Technical Digest, 34, 4, 1, p. 861. This arrangement can suppress the reaction between the HfO₂ film and the polysilicon film, as well as preventing B contained in the polysilicon film from diffusing into the silicon substrate through the HfO₂ film.

In the above prior art example, an SiON film, an HfO₂ film, an SiN film, and a polysilicon film are formed above a silicon substrate in that order. However, since the dielectric constant of the HfO₂ film is approximately 25 and that of the SiN film is approximately 7.5, forming the SiN film on the HfO₂ film increases the equivalent oxide thickness of the entire gate insulating film.

Furthermore, with the above prior art example, the PMOS threshold voltage still has a large absolute value; that is, the problem of the on-current being small at a low voltage remains.

### SUMMARY OF THE INVENTION

The present invention has been devised in view of the above problems. It is, therefore, an object of the present invention to provide a semiconductor device including a gate insulating film which has a small equivalent oxide thickness and whose reaction with the gate electrode is suppressed.

Another object of the present invention is to provide a semiconductor device including a gate insulating film which has a small equivalent oxide thickness and which prevents diffusion of impurities from the gate electrode.

Still another object of the present invention is to provide a semiconductor device including a gate insulating film capable of reducing the absolute value of the PMOS threshold voltage.

According to one aspect of the present invention, a semiconductor device comprises a silicon substrate, a gate insulating film formed on the silicon substrate, and a gate electrode formed on the gate insulating film. The gate insulating film includes a first insulating film, a second insulating film formed on the first insulating film, and a metal nitride film formed on the second insulating film.

According to another aspect of the present invention, a semiconductor device comprises a silicon substrate, a gate insulating film formed on the silicon substrate, and a gate electrode formed on the gate insulating film. The gate insulating film includes a first insulating film, a second insulating film formed on the first insulating film, and a metal oxynitride film formed on the second insulating film.

According to other aspect of the preset invention, a semiconductor device comprises a silicon substrate, a gate insulating film formed on the silicon substrate, and a gate electrode formed on the gate insulating film. The gate insulating film includes a silicon containing oxide film, and a metal nitride film formed on the silicon containing oxide film.

According to other aspect of the present invention, a semiconductor device comprises a silicon substrate, a gate insulating film formed on the silicon substrate, and a gate electrode formed on the gate insulating film. The gate insulating film includes a silicon containing oxide film, and a metal oxynitride film formed on the silicon containing oxide film.

Other and further objects, features and advantages of the invention will appear more fully from the following description.

### BRIEF DESCRIPTION OF THE DRAWINGS

FIG. 1 is a cross-sectional view of a semiconductor device according to a first embodiment.

FIG. 2 is a cross-sectional views illustrating a method for manufacturing a semiconductor device according to a first embodiment.

FIG. 3 is a cross-sectional views illustrating a method for manufacturing a semiconductor device according to a first embodiment.

FIG. 4 is a cross-sectional views illustrating a method for manufacturing a semiconductor device according to a first embodiment.

FIG. 5 is a cross-sectional views illustrating a method for manufacturing a semiconductor device according to a first embodiment.

FIG. 6 is a cross-sectional views illustrating a method for manufacturing a semiconductor device according to a first embodiment.

FIG. 7 is a cross-sectional views illustrating a method for manufacturing a semiconductor device according to a first embodiment.

FIG. 8 is a cross-sectional views illustrating a method for manufacturing a semiconductor device according to a first embodiment.

FIG. 9 is a cross-sectional views illustrating a method for manufacturing a semiconductor device according to a first embodiment.

FIG. 10 is a cross-sectional views illustrating a method for manufacturing a semiconductor device according to a first embodiment.

FIG. 11 is a cross-sectional view of a semiconductor device according to a second embodiment.

FIG. 12 is a cross-sectional views illustrating a method for manufacturing a semiconductor device according to a second embodiment.

FIG. 13 is a cross-sectional views illustrating a method for manufacturing a semiconductor device according to a second embodiment.

FIG. 14 is a cross-sectional views illustrating a method for manufacturing a semiconductor device according to a second embodiment.

FIG. 15 is a cross-sectional view of a semiconductor device according to a third embodiment.

FIG. 16 is a cross-sectional views illustrating a method for manufacturing a semiconductor device according to a third embodiment.

FIG. 17 is a cross-sectional views illustrating a method for manufacturing a semiconductor device according to a third embodiment.

FIG. 18 is a cross-sectional views illustrating a method for manufacturing a semiconductor device according to a third embodiment.

FIG. 19 is a cross-sectional view of a semiconductor device according to a fourth embodiment.

FIG. 20 is a cross-sectional views illustrating a method for manufacturing a semiconductor device according to a fourth embodiment.

FIG. 21 is a cross-sectional views illustrating a method for manufacturing a semiconductor device according to a fourth embodiment.

FIG. 22 is a cross-sectional views illustrating a method for manufacturing a semiconductor device according to a fourth embodiment.

FIG. 23 is a cross-sectional view of a semiconductor device according to a fifth embodiment.

FIG. 24 is a cross-sectional views illustrating a method for manufacturing a semiconductor device according to a fifth embodiment.

FIG. 25 is a cross-sectional views illustrating a method for manufacturing a semiconductor device according to a fifth embodiment.

FIG. 26 is a cross-sectional views illustrating a method for manufacturing a semiconductor device according to a fifth embodiment.

### DETAILED DESCRIPTION OF THE PREFERRED EMBODIMENTS

### First Embodiment

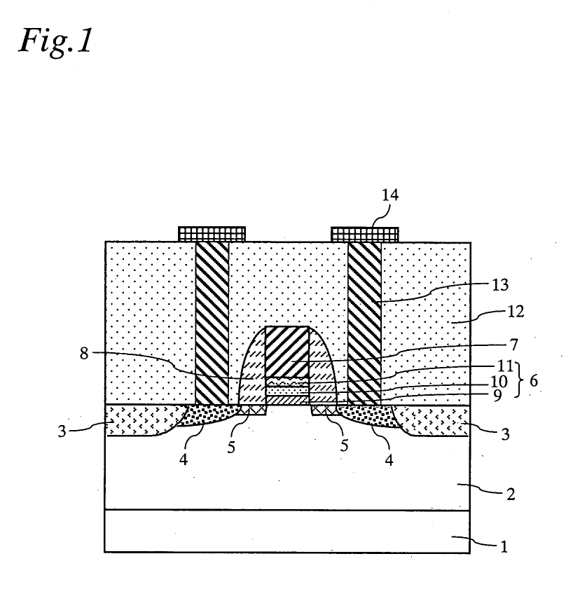

FIG. 1 is a cross-sectional view of a semiconductor device according to a first embodiment of the present invention.

As shown in FIG. 1, in a silicon substrate 1 are formed a diffusion layer 2, device separation regions 3, source/drain regions 4, and extension regions 5. Further, a gate insulating film 6 is formed on the silicon substrate 1, and a gate electrode 7 is formed on the gate insulating film 6. A sidewall 8 is formed on the sides of the gate insulating film 6 and the gate electrode 7. According to the present embodiment, the gate insulating film 6 is made up of a first insulating film 9, a second insulating film 10 formed on the first insulating film 9, and a metal nitride film 11 formed on the second insulating film 10. It should be noted that in FIG. 1, reference numeral 12 denotes an interlayer insulating film, 13 denotes contacts, and 14 denotes a wiring layer.

A silicon containing oxide film may be used as the first insulating film 9. Examples of silicon containing oxide films include: oxides (films) formed by wet oxidation (chemical oxidation); RTO (Rapid Thermal Oxidation) films formed by lamp annealing; insulating films formed of H₂ (hydrogen) and O₂ (oxygen), or H₂ and N₂O (dinitrogen monoxide); and SiON (silicon oxynitride) films. An SiON film is preferably used since it has a high film density.

When the first insulating film 9 contains nitrogen (N), the nitrogen content is preferably between 0.5 atm % and 30 atm %. With a pMOS device, if the nitrogen content is lower than 0.5 atm %, the first insulating film 9 may react with the second insulating film 10, and dopants, such as boron (B), contained in the gate electrode of polysilicon may diffuse. If, on the other hand, the nitrogen content is higher than 30 atm %, the threshold voltage Vth is “shifted toward the negative side” due to positive charge attributed to formation of Si—N bonds. That is, setting the nitrogen content to a value within the above range prevents the reaction at the interface and the diffusion of the dopants, as well as preventing the threshold voltage Vth from being shifted, making it possible to form a device having good electrical characteristics.

The first insulating film 9 may be a multilayer film (or a film stack) made of two or more oxides, instead of a single-layer film made of a single oxide. For example, it may be a multilayer film made up, of an SiON film and an SiO₂ film. In this case, either the SiO₂ film is formed on the SiON film or the SiON film is formed on the SiO₂ film.

A High-k film may be used as the second insulating film 10. Specifically, the second insulating film 10 preferably: (1) has a relative permittivity of approximately 10-30; and (2) can be used for both pMOS and nMOS devices. That is, it is preferably made of a material whose barrier heights on the conduction band side and the valence band side are equally large.

Since an SiO₂ film has a relative permittivity of approximately 3.9, the second insulating film 10 must be made of a material having a relative permittivity larger than this value. However, when the relative permittivity is too large, a large number of lines of electric force leak around the gate, substantially preventing the actual capacitance of the gate insulating film from increasing. On the other hand, to reduce the gate leakage current due to the tunneling current, the second insulating film 10 is preferably formed of a material having a large bandgap. However, materials with a large relative permittivity tend to have a small bandgap.

For reasons explained above, the second insulating film 10 is preferably made of one or more materials selected from the group consisting of MgO, Sc₂O₃, Y₂O₃, La₂O₃, Pr₂O₃, Nd₂O₃, Sm₂O₃, EuO, Gd₂O₃, Tb₂O₃, Dy₂O₃, Ho₂O₃, Er₂O₃, Tm₂O₃, Lu₂O₃, ZrO₂, HfO₂, and Al₂O₃. That is, the second insulating film 10 may be a single-layer metal oxide film such as an MgO film, Sc₂O₃ film, Y₂O₃ film, La₂O₃ film, Pr₂O₃ film, Nd₂O₃ film, Sm₂O₃ film, EuO film, Gd₂O₃ film, Tb₂O₃ film, Dy₂O₃ film, Ho₂O₃ film, Er₂O₃ film, Tm₂O₃ film, Lu₂O₃ film, ZrO₂ film, HfO₂ film or Al₂O₃ film. Or alternatively, it may be a mixed crystal film or multilayer film formed of two or more metal oxides selected from the above group of materials.

Further, the second insulating film 10 may be a multilayer film made up of an SiO₂ film and a film made of one or more materials selected from the group consisting of MgO, Sc₂O₃, Y₂O₃, La₂O₃, Pr₂O₃, Nd₂O₃, Sm₂O₃, EuO, Gd₂O₃, Tb₂O₃, Dy₂O₃, Ho₂O₃, Er₂O₃, Tm₂O₃, Lu₂O₃, ZrO₂, HfO₂, and Al₂O₃.

Still further, the second insulating film 10 may be a mixed crystal film made of a metal oxide and SiO₂. That is, the second insulating film 10 may be made of a mixture of SiO₂ and one or more materials selected from the group consisting of MgO, Sc₂O₃, Y₂O₃, La₂O₃, Pr₂O₃, Nd₂O₃, Sm₂O₃, EuO, Gd₂O₃, Tb₂O₃, Dy₂O₃, Ho₂O₃, Er₂O₃, Tm₂O₃, Lu₂O₃, ZrO₂, HfO₂, and Al₂O₃.

Still further, the second insulating film 10 may be a multilayer film made up of an SiO₂ film and a film made of a mixture of SiO₂ and one or more materials selected from the group consisting of MgO, Sc₂O₃, Y₂O₃, La₂O₃, Pr₂O₃, Nd₂O₃, Sm₂O₃, EuO, Gd₂O₃, Tb₂O₃, Dy₂O₃, Ho₂O₃, Er₂O₃, Tm₂O₃, Lu₂O₃, ZrO₂, HfO₂, and Al₂O₃.

The metal nitride film 11 may be made of nitride of a single metal. For example, it may be an AlN (aluminum nitride) film, an Hf₃N₄ (hafnium nitride) film, an SiN (silicon nitride) film, etc.

The present embodiment forms the metal nitride film 11 between the second insulating film 10 and the gate electrode 7, which makes it possible to prevent reaction between the second insulating film 10 and the gate electrode 7. Furthermore, this arrangement can prevent impurities in the gate electrode 7 from diffusing into the first insulating film 9 and further into the silicon substrate 1 through the second insulating film 10.

Metal nitride films have higher relative permittivity than SiN films. For example, the relative permittivity of an AlN film is approximately 11, while that of an SiN film is approximately 7.5. Therefore, the present embodiment can reduce the equivalent oxide thickness of the entire gate insulating film, as compared to when an SiN film is formed between the High-k film and the gate electrode.

The first insulating film 9 preferably has a film thickness between 0.5 nm and 1.0 nm (that is, an equivalent oxide thickness between 0.5 nm and 1.0 nm). A suitable film thickness for the second insulating film 10, on the other hand, varies depending on its relative permittivity. When the second insulating film 10 is an HfO₂ film (having a relative permittivity of approximately 25), the film thickness is preferably 5 nm or less (corresponding to an equivalent oxide thickness of 0.8 nm or less). When the second insulating film 10 is an HfAlOₓ film or HfSiOₓ film (having a relative permittivity of approximately 15), on the other hand, the film thickness is preferably 3 nm or less (corresponding to an equivalent oxide thickness of 0.8 nm or less). Further, the metal nitride film 11 preferably has a film thickness between 0.3 nm and 1.0 nm (that is, an equivalent oxide thickness between 0.1 nm and 0.4 nm). It should be noted that the equivalent oxide thickness of the entire gate insulating film 6 must be set between 1.2 nm and 1.5 nm.

For example, assume the following: the first insulating film 9 is a multilayer film made up of an SiON film and an SiO₂ film; the second insulating film 10 is an HfAlOₓ film; and the metal nitride film 11 is an AlN film. In such a case, if the film thickness of the first insulating film 9 is set to 0.7 nm (corresponding to an equivalent oxide thickness of 0.7 nm), that of the second insulating film 10 is set to 1.5 nm (corresponding to an equivalent oxide thickness of 0.4 nm), and that of the metal nitride film 11 is set to 0.5 nm (corresponding to an equivalent oxide thickness of 0.2 nm), then the equivalent oxide thickness of the entire gate insulating film 6 is 1.3 nm.

That is, when the equivalent oxide thickness (of the gate insulating film 6) is between 1.2 nm and 1.5 nm, the film thicknesses of the first insulating film 9 and the metal nitride film 11 are preferably set to 1 nm or less in order to increase the thickness of the second insulating film 10 (High-k film) as much as possible. On the other hand, the first insulating film 9 and the metal nitride film 11 each must have a thickness larger than a certain value to properly function. Therefore, as described above, the film thickness of the first insulating film 9 is preferably between 0.5 nm and 1.0 nm, while that of the metal nitride film 11 is preferably between 0.3 nm and 1.0 nm. In other words, the second insulating film 10 is preferably approximately 3 to 6 times thicker than the first insulating film 9 and the metal nitride film 11. This arrangement can reduce the gate leakage current.

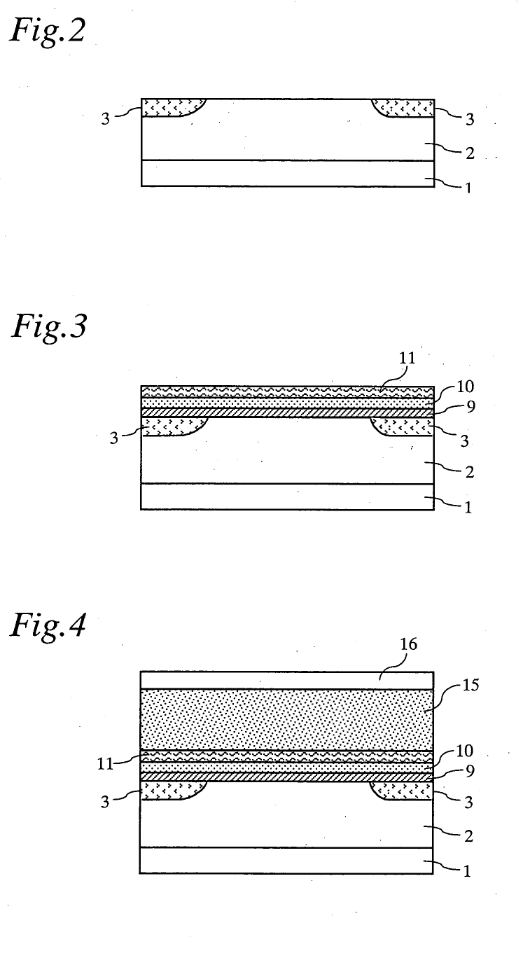

A description will be given of a method for manufacturing the semiconductor device according to the present embodiment with reference to FIGS. 2 to 10. It should be noted that in these figures, components which are the same as those in FIG. 1 will be denoted by like numerals.

First of all, as shown in FIG. 2, a silicon oxide film is buried in predetermined regions of the silicon substrate 1 to form the device separation regions 3 having an STI (Shallow Trench Isolation) structure.

Then, the diffusion layer 2 is formed in the silicon substrate 1 by a photolithographic technique, as shown in FIG. 2. For example, a resist pattern (not shown) is formed on a predetermined region, and n-type or p-type impurities are implanted in the silicon substrate 1 using the resist pattern as a mask. After that, the impurities are diffused through heat treatment to form an n-type or p-type diffusion layer.

Subsequently, the first insulating film 9 is formed on the silicon substrate 1 and then the second insulating film 10 is formed on the first insulating film 9, as shown in FIG. 3. For example, the second insulating film 10 may be formed by an ALD (Atomic Layer Deposition) technique, CVD (Chemical Vapor Deposition) technique, sputtering technique, etc. The ALD technique is preferably used since this technique can grow an extremely uniform film in terms of film thickness and composition and thereby facilitate materials design at the atomic layer level.

After forming the second insulating film 10, PDA (Post Deposition Annealing) is preferably applied to modify the High-k film (the second insulating film 10). For example, when an HfO₂ film is used as the second insulating film 10, the substrate is heat treated at 800° C. under an N₂ gas atmosphere containing a small amount of O₂ for approximately 5 seconds. This arrangement can reduce the amount of hydrogen present due to impurities in the HfO₂ film by a factor of approximately 10. Generally, carbon (C) is readily absorbed to the surface of the High-k film as an impurity. However, the PDA treatment also can remove such an impurity.

Then, the metal nitride film 11 is formed on the second insulating film 10, producing the structure shown in FIG. 3.

For example, the following procedure may be used to form an AlN film as the metal nitride film 11 using an ALD technique. First of all, Al(CH₃)₃ (trimethyl aluminum) and an inert gas are introduced to the surface of the second insulating film 10 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, NH₃ (ammonia) is supplied, together with the inert gas, at a third step. Lastly, at a fourth step, the supply of NH₃ is stopped but the inert gas continues to be supplied so as to remove the excessive NH₃ and byproducts. The above four steps may be repeated to form an AlN film one molecular layer at a time. Thus, an AlN film having a desired film thickness can be formed by controlling the number of reaction cycles.

Further, the AlN film may be formed through thermal decomposition reaction of a raw material while maintaining the surface temperature of the silicon substrate 1 at approximately 420° C. Still another way to form the AlN film is as follows. NH₃ gas is intermittently supplied while maintaining the surface temperature of the silicon substrate 1 at approximately 300° C. At that time, plasma is generated to produce excited species such as NH, NH₂, and NH₃ radicals, which are caused to react with Al, thereby forming the AlN film.

A similar procedure may be used to form an Hf₃N₄ film as the metal nitride film 11. In this case, examples of Hf (hafnium) materials include HfCl₄ (hafnium tetrachloride), Hf[OC(CH₃)₂CH₂OCH₃]₄ (tetrakis(1-methoxy-2-methyl-2-propoxy)hafnium). Hf[OC(CH₃)₃]₄ (tetra-t-butoxyhafnium), Hf[N(CH₃)₂]₄ (tetrakis(dimethylamino)hafnium), Hf[N(C₂H₅)₂]₄ (tetrakis(diethylamino)hafnium), Hf[N(C₂H₅)(CH₃)]₄ (tetrakis(ethylmethylamino)hafnium), Hf(NO₃)₄ (hafnium nitrate), and Hf(C₁₁H₁₉O₂)₄ (tetrakis(dipivaloylmethanato)hafnium).

It should be noted that the second insulating film 10 and the metal nitride film 11 may be formed either in the same chamber or in different chambers. When they are formed in different chambers, the substrate is preferably transferred from the chamber in which the second insulating film 10 is formed to the chamber in which the metal nitride film 11 is formed without breaking the vacuum. Avoiding exposure of the substrate to the atmosphere can prevent foreign objects such as carbon and water from attaching to it.

After forming the metal nitride film 11, a polysilicon film 15 is formed thereon as a gate electrode material. The polysilicon film 15 may be formed by, for example, a CVD technique.

After forming the polysilicon film 15, an SiO₂ film 16 is formed thereon as a hard mask material, as shown in FIG. 4.

After forming the SiO₂ film 16, an antireflective film (not shown) may be formed thereon. When the resist film subsequently formed on the antireflective film is patterned, the antireflective film absorbs the exposure light which has passed through the resist film, functioning to eliminate the reflection of the exposure light at the interface between the resist film and the antireflective film. A film predominantly composed of an organic substance and formed by, for example, the spin coat method, etc. may be used as the antireflective film.

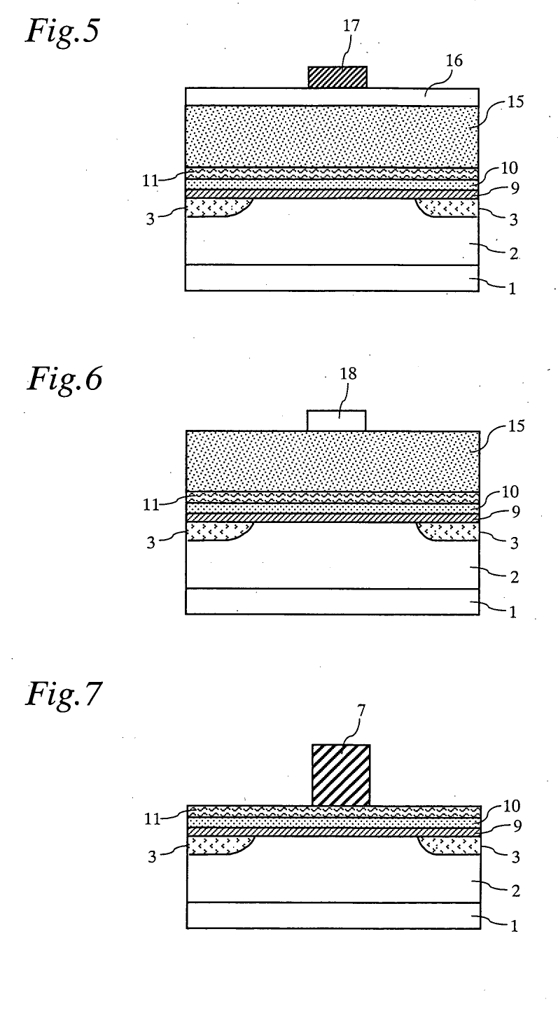

Then, a resist film (not shown) is formed on the SiO₂ film 16, and a resist pattern 17 having a desired line width is formed by a photolithographic technique, producing the structure shown in FIG. 5.

Then, the SiO₂ film 16 is dry-etched using the resist pattern 17 as a mask. After that, the resist pattern 17, which is no longer necessary, is removed, producing an SiO₂ film pattern 18 which acts as a hard mask, as shown in FIG. 6.

Then, the polysilicon film 15 is dry-etched using the SiO₂ film pattern 18 as a mask. The etching gas may consist of one or more types of gases selected from the group consisting of BCl₃, Cl₂, HBr, CF₄, O₂, Ar, N₂, and He, for example.

FIG. 7 shows the state of the components immediately after the polysilicon film 15 is dry-etched. As shown in FIG. 7, the polysilicon film 15 has been etched to produce the gate electrode 7.

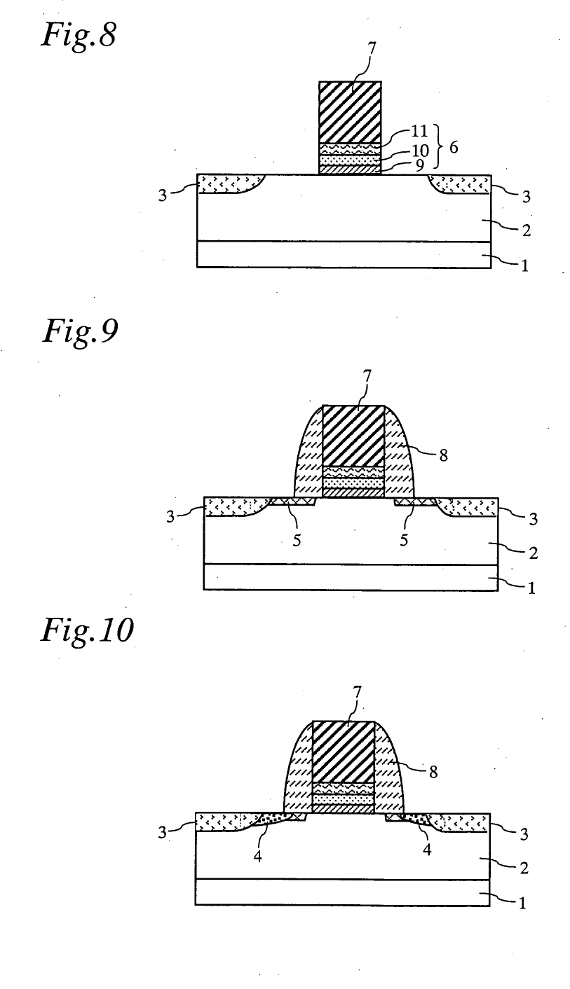

Then, the metal nitride film 11, the second insulating film 10, and the first insulating film 9 are etched using the SiO₂ film pattern 18 as a mask, producing the structure shown in FIG. 8. As shown in the figure, the first insulating film 9, the second insulating film 10, and the metal nitride film 11 collectively constitute the gate insulating film 6 after they are patterned (etched).

Then, impurities are ion-implanted in the diffusion layer 2 of the silicon substrate 1 using the gate electrode 7 as a mask. After that, activation is carried out through heat treatment to form the extension regions 5.

Then, the sidewall 8 is formed by a known method, producing the structure shown in FIG. 9. At that time, the sidewall 8 is formed on the sides of the gate electrode 7 and the gate insulating film 6.

Then again, impurities are ion-implanted in the diffusion layer 2 of the silicon substrate 1, and activation is carried out through heat treatment to form the source/drain regions 4, as shown in FIG. 10. After that, the interlayer insulating film 12, the contacts 13, and the wiring 14 are formed, producing the structure shown in FIG. 1.

The present embodiment forms the metal nitride film between the second insulating film (High-k film) and the gate electrode, which makes it possible to prevent unfavorable reactions between the High-k film and the gate electrode, such as silicification. Furthermore, this arrangement can prevent impurities in the gate electrode from diffusing into the gate insulating film and further into the silicon substrate due to heat treatment performed after the ion implantation and thereby prevent degradation of the characteristics of the gate insulating film, making it possible to produce a highly reliable semiconductor device having good electrical characteristics.

The present inventor produced a sample device as follows. An SiO₂ film was formed on a silicon substrate to a film thickness of 0.8 nm and an HfO₂ film was formed on the SiO₂ film to a film thickness of 2.5 nm by an ALD technique. After that, PDA treatment was applied to the substrate and then an AlN film was formed on the HfO₂ film to a film thickness of 0.5 nm by an ALD technique. Then, after forming a gate electrode made up of a polysilicon film having a film thickness of 150 nm, B⁺ was ion-implanted in the silicon substrate using the gate electrode as a mask. At that time, the implantation energy was 5 keV and the amount of implantation was 3×10¹⁵ cm⁻². After that, the sample was activated through heat treatment at 1,050° C. under an N₂ atmosphere for 1 second.

The produced sample was subjected to Back-Side SIMS (Secondary Ion Mass Spectrometry) to check the interfaces between the HfO₂ film and the SiO₂ film and between the SiO₂ film and the silicon substrate. No boron (B) was detected, and any degradation in characteristics (such as an increase in the equivalent oxide thickness) was not observed. The gate insulating film of the sample had a sufficient capacitance for the sample to serve as a 65 nm generation or later MOS transistor. Furthermore, the PMOS threshold voltage Vth was measured to be approximately −0.3 V to 0 V.

For comparison, the present inventor produced another sample device as follows. An SiO₂ film was formed on a silicon substrate to a film thickness of 0.8 nm and an HfO₂ film was formed on the SiO₂ film to a film thickness of 2.5 nm by an ALD technique. After that, PDA treatment was applied to the substrate and then a gate electrode made up of a polysilicon film having a film thickness of 150 nm was formed. Then, B⁺ was ion-implanted in the silicon-substrate using this gate electrode as a mask. At that time, the implantation energy was 5 keV and the amount of implantation was 3×10¹⁵ cm⁻². Then, the sample was activated through heat treatment at 1,050° C. under an N₂ atmosphere for 1 second.

The produced sample was also subjected to Back-Side SIMS (Secondary Ion Mass Spectrometry) to-check the interfaces between the HfO₂ film and the SiO₂ film and between the SiO₂ film and the silicon substrate. Boron (B) was detected at an overall concentration of 1×10¹⁸ atoms/cm³. The PMOS threshold voltage Vth was measured to be approximately −1.0 V to −0.7 V.

### Second Embodiment

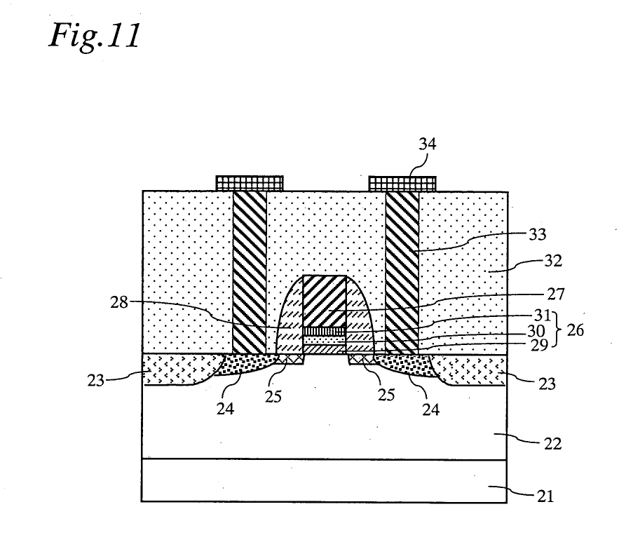

FIG. 11 is a cross-sectional view of a semiconductor device according to a second embodiment of the present invention.

As shown in FIG. 11, in a silicon substrate 21 are formed a diffusion layer 22, device separation regions 23, source/drain regions 24, and extension regions 25. Further, a gate insulating film 26 is formed on the silicon substrate 21, and a gate electrode 27 is formed on the gate insulating film 26. A sidewall 28 is formed on the sides of the gate insulating film 26 and the gate electrode 27. The gate insulating film 26 is made up of a first insulating film 29, a second insulating film 30 formed on the first insulating film 29, and a metal nitride film 31 formed on the second insulating film 30. It should be noted that in FIG. 11, reference numeral 32 denotes an interlayer insulating film, 33 denotes contacts, and 34 denotes a wiring layer.

The present embodiment is characterized in that the metal nitride film 31 is a mixed film made of nitrides of two or more metals. For example, the metal nitride film 31 may be a mixed film made up of an AlN film and an Hf₃N₄ film; that is, it is formed of Al, Hf, and N.

The first insulating film (29) and the second insulating film (30) may be the same as those of the first embodiment.

The first insulating film 29 preferably has a film thickness between 0.5 nm and 1.0 nm (that is, an equivalent oxide thickness between 0.5 nm and 1.0 nm). A suitable film thickness for the second insulating film 30, on the other hand, varies depending on its relative permittivity. When the second insulating film 30 is an HfO₂ film (having a relative permittivity of approximately 25), the film thickness is preferably 5 nm or less (corresponding to an equivalent oxide thickness of 0.8 nm or less). When the second insulating film 30 is an HfAlOₓ film or HfSiOₓ film (having a relative permittivity of approximately 15), on the other hand, the film thickness is preferably 3 nm or less (corresponding to an equivalent oxide thickness of 0.8 nm or less). Further, the metal nitride film 31 preferably has a film thickness between 0.3 nm and 1.0 nm (that is, an equivalent oxide thickness between 0.1 nm and 0.4 nm). It should be noted that the equivalent oxide thickness of the entire gate insulating film 26 must be set between 1.2 nm and 1.5 nm.

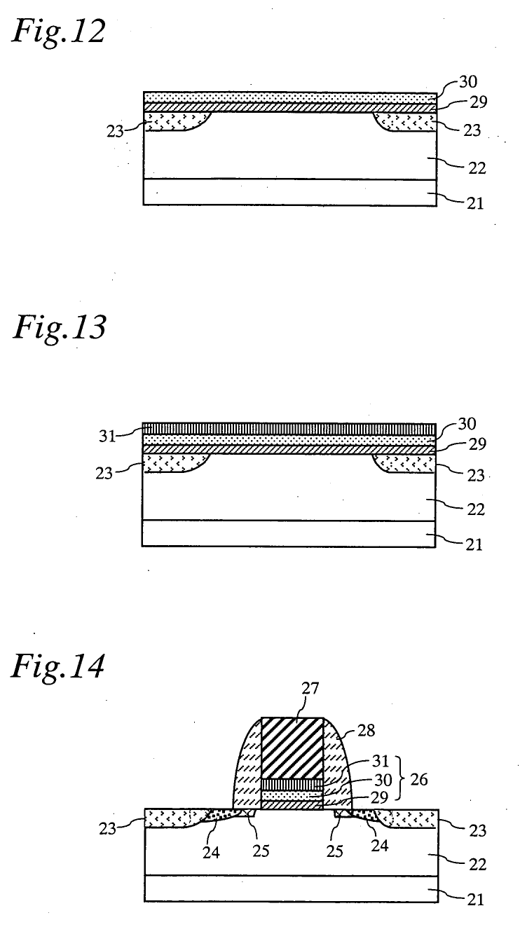

A description will be given of a method for manufacturing the semiconductor device according the present embodiment with reference to FIGS. 12 to 14. It should be noted that in these figures, components which are the same as those in FIG. 11 will be denoted by like numerals.

First of all, the device separation regions 23 and the diffusion layer 22 are formed in the silicon substrate 21 by the method described in connection with the first embodiment shown in FIGS. 2 and 3. Then, the first insulating film 29 is formed on the silicon substrate 21, and the second insulating film 30 is formed on the first insulating film 29, producing the structure shown in FIG. 12.

Then, the metal nitride film 31 is formed on the second insulating film 30, producing the structure shown in FIG. 13. For example, the following procedure may be used to form a mixed film of AlN and Hf₃N₄ as the metal nitride film 31 using an ALD technique.

First of all, Al(CH₃)₃ (trimethyl aluminum) and an inert gas are introduced to the surface of the second insulating film 30 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, NH₃ (ammonia) is supplied, together with the inert gas, at a third step. Lastly, at a fourth step, the supply of NH₃ is stopped but the inert gas continues to be supplied so as to remove the excessive NH₃ and byproducts. The above four steps are repeated a plurality of times to form an AlN film having a desired film thickness.

Then, the process of forming an Hf₃N₄ film is performed. First of all, HfCl₄ (hafnium tetrachloride) and an inert gas are introduced to the surface of the AlN film at a first step, the HfCl₄ being a raw material gas. Then, at a second step, the supply of the raw material gas is stopped but the inert gas continues to be supplied so as to remove the excessive HfCl₄ and byproducts. After that, NH₃ (ammonia) is supplied, together with the inert gas, at a third step. Lastly, at a fourth step, the supply of NH₃ is stopped but the inert gas continues to be supplied so as to remove the excessive NH₃ and byproducts. The above four steps are repeated a plurality of times to form an Hf₃N₄ film having a desired film thickness.

It should be noted that the above mixed film may be formed in such a way that the Hf₃N₄ film is formed before forming the AlN film.

Further, the mixed film may be formed by repeating the formation of an AlN film and that of an Hf₃N₄ film alternately. For example, n1 number of reaction cycles may be performed to form an AlN film and then n2 number of reaction cycles may be performed to form an Hf₃N₄ film. These reaction cycles for the AlN film and the Hf₃N₄ film collectively constitute a single complete formation cycle. This complete formation cycle may be repeated N times to form the mixed film. It should be noted that it may be arranged that the n2 number of reaction cycles for the Hf₃N₄ film are performed before performing the n1 number of reaction cycles for the AlN film. Then, such a complete formation cycle may be repeated N times to form the mixed film.

Further, the above mixed film may be formed through. thermal decomposition of a raw material while maintaining the surface temperature of the silicon substrate 21 at approximately 420° C. Still another way to form the mixed film is as follows. NH₃ gas is intermittently supplied while maintaining the surface temperature of the silicon substrate 21 at 300° C. At that time, plasma is generated to produce excited species such as NH, NH₂, and NH₃ radicals, which are caused to react with Al and Hf, forming the mixed film.

It should be noted that examples of materials for the Hf₃N₄ film include Hf[OC(CH₃)₂CH₂OCH₃]₄ (tetrakis(1-methoxy-2-methyl-2-propoxy)hafnium), Hf[OC(CH₃)₃]₄ (tetra-t-butoxyhafnium), Hf[N(CH₃)₂]₄ (tetrakis(dimethylamino)hafnium), Hf[N(C₂H₅)₂]₄ (tetrakis(diethylamino)hafnium), Hf[N(C₂H₅)(CH₃)]₄ (tetrakis(ethylmethylamino)hafnium), Hf(NO₃)₄ (hafnium nitrate), and Hf(C₁₁H₁₉O₂)₄ (tetrakis(dipivaloylmethanato)hafnium), in addition to HfCl₄ (hafnium tetrachloride).

It should be noted that the second insulating film 30 and the metal nitride film 31 may be formed either in the same chamber or in different chambers. When they are formed in different chambers, the substrate is preferably transferred from the chamber in which the second insulating film 30 is formed to the chamber in which the metal nitride film 31 is formed without breaking the vacuum. Avoiding exposure of the substrate to the atmosphere can prevent foreign objects such as dust and water from attaching to it.

After the metal nitride film 31 is formed, the gate electrode 27, the gate insulating film 26, the extension regions 25, the sidewall 28, and the source/drain regions 24 are formed by the method described in connection with the first embodiment shown in FIGS. 4 to 10, producing the structure shown in FIG. 14. After that, the interlayer insulating film 32, the contacts 33, and the wiring 34 are formed, producing the structure shown in FIG. 11.

The present embodiment forms the mixed film of two or more metal nitrides between the second insulating film (High-k film) and the gate electrode, which makes it possible to prevent silicification reaction, etc. between the High-k film and the gate electrode. Furthermore, this arrangement can prevent impurities in the gate electrode from diffusing into the gate insulating film and further into the silicon substrate due to heat treatment performed after the ion implantation, as well as reducing the absolute value of the PMOS threshold voltage. Therefore, degradation of the characteristics of the gate insulating film can be prevented, making it possible to produce a highly reliable semiconductor device having good electrical characteristics.

Furthermore, according to the present embodiment, the mixing ratio of the metal nitrides making up the mixed film (the metal nitride film) may be changed to change the relative permittivity, etc. of the metal nitride film. That is, the characteristics of the gate insulating film, such as the equivalent oxide thickness and the threshold voltage, can be changed by changing the mixing ratio of the metal nitrides.

### Third Embodiment

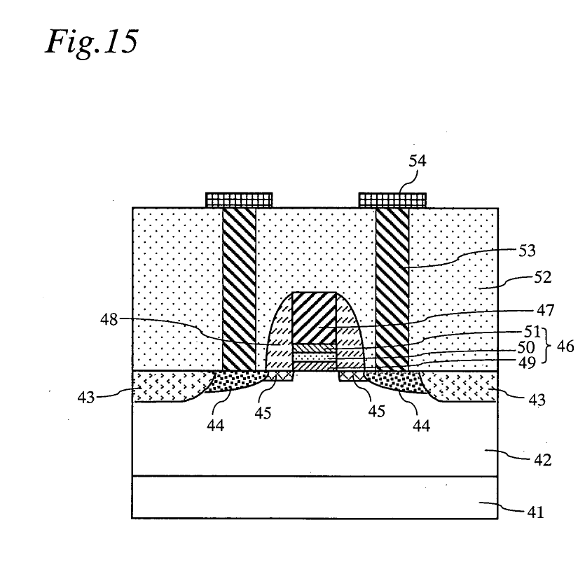

FIG. 15 is a cross-sectional view of a semiconductor device according to a third embodiment of the present invention.

As shown in FIG. 15, in a silicon substrate 41 are formed a diffusion layer 42, device separation regions 43, source/drain regions 44, and extension regions 45. Further, a gate insulating film 46 is formed on the silicon substrate 41, and a gate electrode 47 is formed on the gate insulating film 46. A sidewall 48 is formed on the sides of the gate insulating film 46 and the gate electrode 47. The present embodiment is characterized in that the gate insulating film 46 is made up of a first insulating film 49, a second insulating film 50 formed on the first insulating film 49, and a metal oxynitride film 51 formed on the second insulating film 50. It should be noted that in FIG. 15, reference numeral 52 denotes an interlayer insulating film, 53 denotes contacts, and 54 denotes a wiring layer.

The first insulating film (49) and the second insulating film (50) may be the same as those of the first embodiment.

An AlON (aluminum oxynitride) film, an HfON (hafnium oxynitride) film, etc. may be used as the metal oxynitride film 51.

The first insulating film 49 preferably has a film thickness between 0.5 nm and 1.0 nm (that is, an equivalent oxide thickness between 0.5 nm and 1.0 nm). A suitable film thickness for the second insulating film 50, on the other hand, varies depending on its relative permittivity. When the second insulating film 50 is an HfO₂ film (having a relative permittivity of approximately 25), the film thickness is preferably 5 nm or less (corresponding an equivalent oxide thickness of 0.8 nm or less). When the second insulating film 50 is an HfAlOₓ film or HfSiOₓ film (having a relative permittivity of approximately 15), on the other hand, the film thickness is preferably 3 nm or less (corresponding to an equivalent oxide thickness of 0.8 nm or less). Further, the metal oxynitride film 51 preferably has a film thickness between 0.3 nm and 1.0 nm (that is, an equivalent oxide thickness between 0.1 nm and 0.4 nm). It should be noted that the equivalent oxide thickness of the entire gate insulating film 46 must be set between 1.2 nm and 1.5 nm.

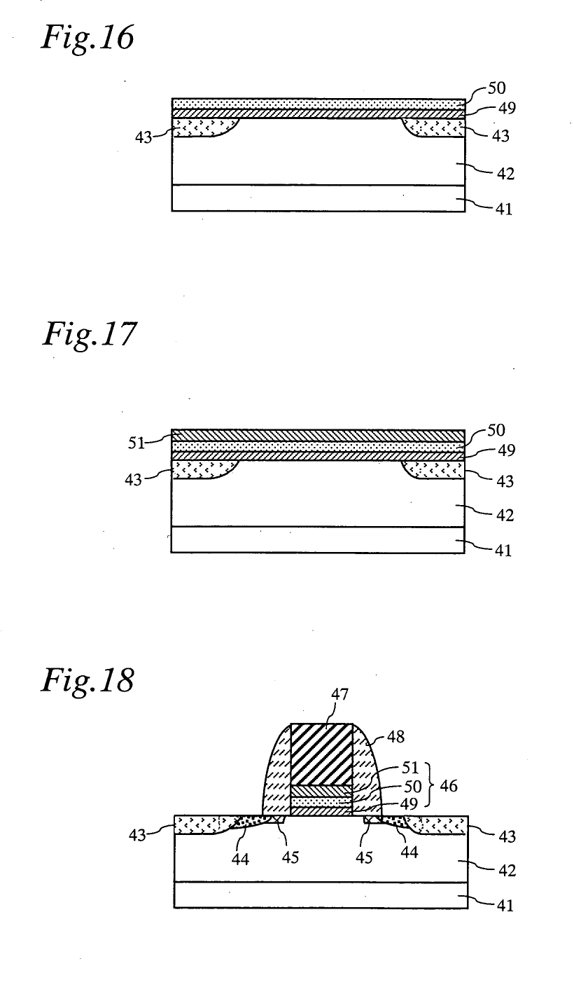

A description will be given of a method for manufacturing the semiconductor device according to the present embodiment with reference to FIGS. 16 to 18. It should be noted that in these figures, components which are the same as those in FIG. 15 will be denoted by like numerals.

First of all, the device separation regions 43 and the diffusion layer 42 are formed in the silicon substrate 41 by the method described in connection with the first embodiment shown in FIGS. 2 and 3. Then, the first insulating film 49 is formed on the silicon substrate 41, and the second insulating film 50 is formed on the first insulating film 49, producing the structure shown in FIG. 16.

Then, the metal oxynitride film 51 is formed on the second insulating film 50, producing the structure shown in FIG. 17. For example, the following procedure may be used to form an AlON film as the metal oxynitride film 51 using an ALD technique.

First of all, Al(CH₃)₃ (trimethyl aluminum) and an inert gas are introduced to the surface of the second insulating film 50 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, NH₃ (ammonia) is supplied, together with the inert gas, at a third step. Lastly, at a fourth step, the supply of NH₃ is stopped but the inert gas continues to be supplied so as to remove the excessive NH₃ and byproducts. The above four steps are repeated a plurality of times to form an AlN film having a desired film thickness.

Then, PDA treatment is applied to the substrate under an atmosphere of N₂ gas added with a small amount of oxygen. This can modify the second insulating film 50 (High-k film) as well as oxidizing the AlN film into an AlON film. That is, the AlN film formed at a low temperature may be heat treated to form a dense AlN film or AlON film. The dense AlN film can prevent impurities such as B (boron) from penetrating through even if it is physically and electrically thin, making it possible to produce a high-performance transistor having a small equivalent oxide thickness.

A similar procedure may be used to form an HfON film as the metal oxynitride film 51. That is, HfCl₄ (hafnium tetrachloride) and an inert gas are introduced to the surface of the second insulating film 50 at a first step, the HfCl₄ being a raw material gas. Then, at a second step, the supply of the raw material gas is stopped but the inert gas continues to be supplied so as to remove the excessive HfCl₄ and byproducts. After that, NH₃ (ammonia) is supplied, together with the inert gas, at a third step. Lastly, at a fourth step, the supply of NH₃ is stopped but the inert gas continues to be supplied so as to remove the excessive NH₃ and byproducts. The above four steps are repeated a plurality of times to form an Hf₃N₄ film having a desired film thickness. Then, PDA treatment is applied to the substrate under an atmosphere of N₂ gas added with a small amount of oxygen. This can modify the second insulating film 50 (High-k film) as well as oxidizing the Hf₃N₄ film into an HfON film.

It should be noted that the following procedures may also be used to form the metal oxynitride film 51.

The following is another procedure used to form an AlON film as the metal oxynitride film 51. First of all, Al(CH₃)₃ and an inert gas are introduced to the surface of the second insulating film 50 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, NH₃ is supplied, together with the inert gas, at a third step. Then, at a fourth step, the supply of NH₃ is stopped but the inert gas continues to be supplied so as to remove the excessive NH₃ and byproducts. Then, oxidizer is supplied, together with the inert gas, at a fifth step. Lastly, at a sixth step, the supply of oxidizer is stopped but the inert gas continues to be supplied so as to remove the excessive oxidizer and byproducts. The above six steps are repeated a plurality of times to form an AlON film having a desired film thickness. Instead of Al(CH₃)₃, HfCl₄ may be used as a raw material and the above steps may be repeated to form an HfON film.

The following is still another procedure used to form an AlON film as the metal oxynitride film 51. First of all, Al(CH₃)₃ and an inert gas are introduced to the surface of the second insulating film 50 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, oxidizer is supplied, together with the inert gas, at a third step. Then, at a fourth step, the supply of oxidizer is stopped but the inert gas continues to be supplied so as to remove the excessive oxidizer and byproducts. Then, NH₃ is supplied, together with the inert gas, at a fifth step. Lastly, at a sixth step, the supply of NH₃ is stopped but the inert gas continues to be supplied so as to remove the excessive NH₃ and byproducts. The above six steps are repeated a plurality of times to form an AlON film having a desired film thickness. Instead of Al(CH₃)₃, HfCl₄ may be used as a raw material and the above steps may be repeated to form an HfON film.

The following is still another procedure used to form an AlON film as the metal oxynitride film 51. First, Al(CH₃)₃ and an inert gas are introduced to the surface of the second insulating film 50 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, NH₃ is supplied, together with the inert gas, at a third step. Lastly, at a fourth step, the supply of NH₃ is stopped but the inert gas continues to be supplied so as to remove the excessive NH₃ and byproducts. The above four steps are repeated a plurality of times to form an AlN film. Then, the process of forming an Al₂O₃ film is performed. Specifically, first, Al(CH₃)₃ and an inert gas are introduced to the surface of the AlN film at a first step, the Al(CH₃)₃ being a raw material gas. Then, at a second step, the supply of the raw material gas is stopped but the inert gas continues to be supplied so as to remove the excessive Al(CH₃)₃ and byproducts. After that, oxidizer is supplied, together with the inert gas, at a third step. Lastly, at a fourth step, the supply of oxidizer is stopped but the inert gas continues to be supplied so as to remove the excessive oxidizer and byproducts. The above four steps are repeated a plurality of times to form an Al₂O₃ film. Then, the above AlN film forming process and Al₂O₃ film forming process are each repeated a predetermined number of times to form an ALON film having a desired film thickness. Instead of Al(CH₃)₃, HfCl₄ may be used as a raw material and the above processes may be repeated to form an HfON film.

The following is yet another procedure used to form an AlON film as the metal oxynitride film 51. First, Al(CH₃)₃ and an inert gas are introduced to the surface of the second insulating film 50 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, NH₃ is supplied, together with the inert gas, at a third step. Lastly, at a fourth step, the supply of NH₃ is stopped but the inert gas continues to be supplied so as to remove the excessive NH₃ and byproducts. The above four steps are repeated n1 number of times to form an AlN film. Then, the process of forming an Al₂O₃ film is performed. Specifically, first, Al(CH₃)₃ and an inert gas are introduced to the surface of the AlN film at a first step, the Al(CH₃)₃ being a raw material gas. Then, at a second step, the supply of the raw material gas is stopped but the inert gas continues to be supplied so as to remove the excessive Al(CH₃)₃ and byproducts. After that, oxidizer is supplied, together with the inert gas, at a third step. Lastly, at a fourth step, the supply of oxidizer is stopped but the inert gas continues to be supplied so as to remove the excessive oxidizer and byproducts. The above four steps are repeated n2 number of times to form an Al₂O₃ film. The above n1 number of reaction cycles for AlN film and n2 number of reaction cycles for Al₂O₃ film collectively constitute a single complete formation cycle. This complete formation cycle may be repeated N times to form an AlON film having a desired film thickness. It should be noted that instead of Al(CH₃)₃, HfCl₄ may be used as a raw material and the above processes may be repeated to form an HfON film.

Examples of oxidizers used in the above processes include H₂O (vapor), O₂ (oxygen), and O₃ (ozone). O₂ (oxygen) activated by plasma may also be used.

Further, according to the present embodiment, an oxynitride film of two or more metals may be used as the metal oxynitride film 51.

For example, a film made of Al, Hf, N, and O may be used as the above metal oxynitride film 51. Specifically, first a mixed film made up of an AlN film and an Hf₃N₄ film is formed by the method described in connection with the second embodiment. Then, PDA treatment is applied to the substrate under an atmosphere of N₂ gas added with a small amount of oxygen. This can form a metal oxynitride film made of Al, Hf, N, and O.

The following is another procedure used to form the above metal oxynitride film 51 (made of Al, Hf, N, and O). First of all, Al(CH₃)₃ and an inert gas are introduced to the surface of the second insulating film 50 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, NH₃ is supplied, together with the inert gas, at a third step. Then, at a fourth step, the supply of NH₃ is stopped but the inert gas continues to be supplied so as to remove the excessive NH₃ and byproducts. Then, oxidizer is supplied, together with the inert gas, at a fifth step. After that, at a sixth step, the supply of oxidizer is stopped but the inert gas continues to be supplied so as to remove the excessive oxidizer and byproducts. Then, HfCl₄ and an inert gas are supplied at a seventh step, the HfCl₄ being a raw material gas. After that, at an eighth step, the supply of the raw material gas is stopped but the inert gas continues to be supplied so as to remove the excessive HfCl₄ and byproducts. Then, NH₃ is supplied, together with the inert gas, at a ninth step. Then, at a tenth step, the supply of NH₃ is stopped but the inert gas continues to be supplied so as to remove the excessive NH₃ and byproducts. After that, oxidizer is supplied, together with the inert gas, at an eleventh step. Lastly, at a twelfth step, the supply of oxidizer is stopped but the inert gas continues to be supplied so as to remove the excessive oxidizer and byproducts. The above twelve steps may be repeated a plurality of times to form a metal oxynitride film made of Al, Hf, N, and O. It should be noted that in this case, Al(CH₃)₃ at the above first step may be replaced by HfCl₄, and HfCl₄ at the above seventh step may be replaced by Al(CH₃)₃.

Further, the above first to sixth steps may be repeated n1 times (n1 number of reaction cycles), and the above seventh to twelfth steps may be repeated n2 times (n2 number of reaction cycles). These n1 number of reaction cycles for AlON film (or HfON film) and n2 number of reaction cycles for HfON film (or AlON film) collectively constitute a single complete formation cycle. This complete formation cycle may be repeated N times to form the metal oxynitride film 51 having a desired film thickness.

Further, the following is still another procedure used to form the metal oxynitride film (51) made of Al, Hf, N, and O.

First of all, Al(CH₃)₃ and an inert gas are introduced to the surface of the second insulating film 50 at a first step, the Al(CH₃)₃ being a raw material gas. Then, at a second step, the supply of the raw material gas is stopped but the inert gas continues to be supplied so as to remove the excessive Al(CH₃)₃ and byproducts. After that, oxidizer is supplied, together with the inert gas, at a third step. Then, at a fourth step, the supply of oxidizer is stopped but the inert gas continues to be supplied so as to remove the excessive oxidizer and byproducts. Then, NH₃ is supplied, together with the inert gas, at a fifth step. After that, at a sixth step, the supply of NH₃ is stopped but the inert gas continues to be supplied so as to remove the excessive NH₃ and byproducts. Then, HfCl₄ and an inert gas are supplied at a seventh step, the HfCl₄ being a raw material gas. After that, at an eighth step, the supply of the raw material gas is stopped but the inert gas continues to be supplied so as to remove the excessive HfCl₄ and byproducts. Then, oxidizer is supplied, together with the inert gas, at a ninth step. Then, at a tenth step, the supply of oxidizer is stopped but the inert gas continues to be supplied so as to remove the excessive oxidizer and byproducts. After that, NH₃ is supplied, together with the inert gas, at an eleventh step. Lastly, at a twelfth step, the supply of NH₃ is stopped but the inert gas continues to be supplied so as to remove the excessive NH₃ and byproducts. The above twelve steps may be repeated a plurality of times to form the metal oxynitride film 51 having a desired film thickness. It should be noted that in this case, Al(CH₃)₃ at the above first step may be replaced by HfCl₄, and HfCl₄ at the above seventh step may be replaced by Al(CH₃)₃.

Further, the above first to sixth steps may be repeated n1 times (n1 number of reaction cycles), and the above seventh to twelfth steps may be repeated n2 times (n2 number of reaction cycles). These n1 number of reaction cycles for AlON film (or HfON film) and n2 number of reaction cycles for HfON film (or AlON film) collectively constitute a single complete formation cycle. This complete formation cycle may be repeated N times to form the metal oxynitride film 51 having a desired film thickness.

It should be noted that examples of materials for the Hf₃N₄ film include Hf[OC(CH₃)₂CH₂OCH₃]₄ (tetrakis(1-methoxy-2-methyl-2-propoxy)hafnium), Hf[OC(CH₃)₃]₄ (tetra-t-butoxyhafnium), Hf[N(CH₃)₂]₄ (tetrakis(dimethylamino)hafnium), Hf[N(C₂H₅)₂]₄ (tetrakis(diethylamino)hafnium), Hf[N(C₂H₅)(CH₃)]₄ (tetrakis(ethylmethylamino)hafnium), Hf(NO₃)₄ (hafnium nitrate), and Hf(C₁₁H₁₉O₂)₄ (tetrakis(dipivaloylmethanato)hafnium), in addition to HfCl₄ (hafnium tetrachloride).

It should be noted that the second insulating film 50 and the metal oxynitride film 51 may be formed either in the same chamber or in different chambers. When they are formed in different chambers, the substrate is preferably transferred from the chamber in which the second insulating film 50 is formed to the chamber in which the metal oxynitride film 51 is formed without breaking the vacuum. Avoiding exposure of the substrate to the atmosphere can prevent foreign objects such as carbon and water from attaching to it.

After the metal oxynitride film 51 is formed, the gate electrode 47, the gate insulating film 46, the extension regions 45, the sidewall 48, and the source/drain regions 44 are formed by the method described in connection with the first embodiment shown in FIGS. 4 to 10, producing the structure shown in FIG. 18. After that, the interlayer insulating film 52, the contacts 53, and the wiring 54 are formed, producing the structure shown in FIG. 15.

The present embodiment forms the metal oxynitride film between the second insulating film (High-k film) and the gate electrode, which makes it possible to prevent silicification reaction, etc. between the High-k film and the gate electrode. Furthermore, this arrangement can prevent impurities in the gate electrode from diffusing into the gate insulating film and further into the silicon substrate due to heat treatment performed after the ion implantation, as well as reducing the absolute value of the PMOS threshold voltage and controlling the NMOS and the PMOS threshold voltages. Therefore, degradation of the characteristics of the gate insulating film can be prevented, making it possible to produce a highly reliable semiconductor device having good electrical characteristics.

Further, the present embodiment can suppress the formation of the interfacial level between the metal oxynitride film and the High-k film due to the difference between their material compositions by adjusting the ratio of the amount of oxygen to the amount of nitrogen contained in the metal oxynitride film.

### Fourth Embodiment

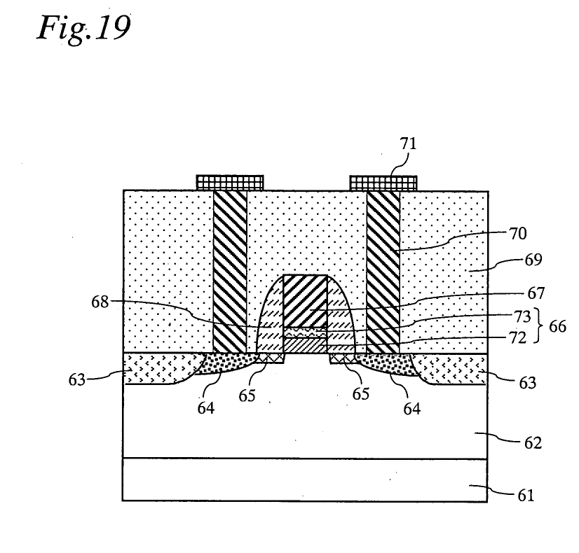

FIG. 19 is a cross-sectional view of a semiconductor device according to a fourth embodiment of the present invention.

As shown in FIG. 19, in a silicon substrate 61 are formed a diffusion layer 62, device separation regions 63, source/drain regions 64, and extension regions 65. Further, a gate insulating film 66 is formed on the silicon substrate 61, and a gate electrode 67 is formed on the gate insulating film 66. A sidewall 68 is formed on the sides of the gate insulating film 66 and the gate electrode 67. It should be noted that in FIG. 19, reference numeral 69 denotes an interlayer insulating film, 70 denotes contacts, and 71 denotes a wiring layer.

The present embodiment is characterized in that the gate insulating film 66 is made up of a silicon containing oxide film 72 and a metal nitride film 73 formed on the silicon containing oxide film 72.

Examples of the silicon containing oxide film 72 include: oxides formed by wet oxidation (chemical oxides); RTO (rapid thermal oxide) films formed by lamp annealing; ISSG (In-Situ Steam Generation) films; insulating films made of H₂ (hydrogen) and O₂ (oxygen), or H₂ and N₂O (dinitrogen monoxide); and SiON (silicon oxynitride) films. An SiON film is preferably used since it has a high film density. It should be noted that the silicon containing oxide film 72 may be a multilayer film (or a film stack) made of two or more oxides, instead of a single-layer film made of a single oxide. For example, it may be a multilayer film made up of an SiON film and an SiO₂ film.

The metal nitride film 73 may be made of nitride of a single metal, or it may be a mixed film made of nitride of two or more metals. For example, an AlN film, an Hf₃N₄ film, or a mixed film made up of these films may be used as the metal nitride film 73.

The silicon containing oxide film of the present embodiment corresponds to the first insulating films of the first and second embodiments. It should be noted that according to the first or second embodiment, the second insulating film (High-k film) is formed between the first insulating film and the metal nitride film. The present embodiment, on the other hand, is configured such that the metal nitride film is directly formed on the silicon containing oxide film. This arrangement allows increasing the film thickness of the silicon containing oxide film, thereby increasing the (carrier) mobility of the gate insulating film.

According to the present embodiment, the gate insulating film has a structure in which the silicon containing oxide film and the metal nitride film are laminated to each other. Since metal nitride films have a comparatively high relative permittivity, the film thickness of the gate insulating film can be reduced while reducing the gate leakage current.

The present embodiment forms the metal nitride film between the silicon containing oxide film and the gate electrode, which makes it possible to prevent impurities in the gate electrode from diffusing into the gate insulating film and further into the silicon substrate due to heat treatment performed after the ion implantation. Thus, degradation of the characteristics of the gate insulating film can be prevented.

Further, the present embodiment can reduce the absolute value of the PMOS threshold voltage as well as controlling the NMOS and the PMOS threshold voltages.

The silicon containing oxide film 72 preferably has a film thickness between 1.0 nm and 1.2 nm (that is, an equivalent oxide thickness between 1.0 nm and 1.2 nm). The metal nitride film 73, on the other hand, preferably has a film thickness between 0.3 nm and 1.0 nm (that is, an equivalent oxide thickness between 0.1 nm and 0.4 nm). It should be noted that the equivalent oxide thickness of the entire gate insulating film 66 must be set between 1.2 nm and 1.5 nm.

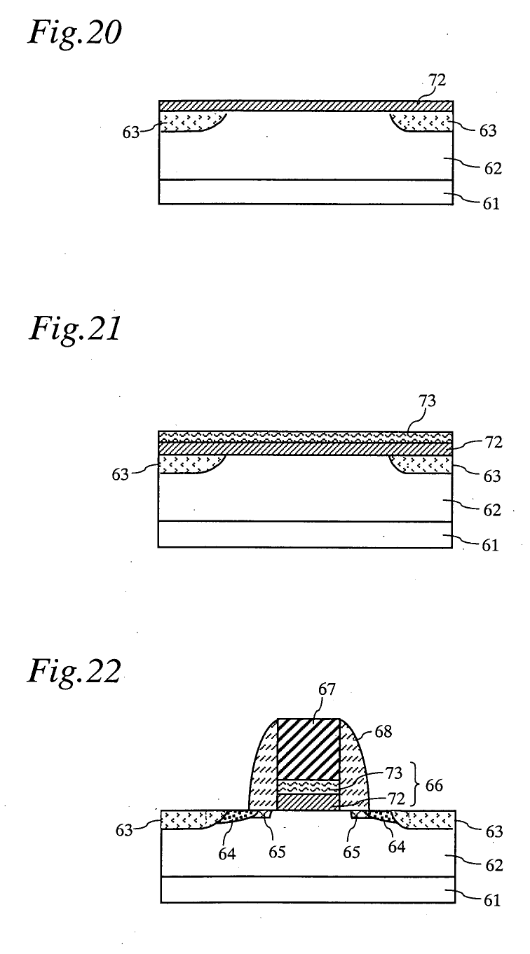

A description will be given of a method for manufacturing the semiconductor device according to the present embodiment with reference to FIGS. 20 to 22. It should be noted that in these figures, components which are the same as those in FIG. 19 will be denoted by like numerals.

First of all, the device separation regions 63 and the diffusion layer 62 are formed in the silicon substrate 61 by the method described in connection with the first embodiment shown in FIGS. 2 and 3. Then, the silicon containing oxide film 72 is formed on the silicon substrate 61, producing the structure shown in FIG. 20.

Then, the metal nitride film 73 is formed on the silicon containing oxide film 72, producing the structure shown in FIG. 21.

When the metal nitride film 73 is an AlN film or Hf₃N₄ film, it may be formed in the same manner as in the first embodiment. When the metal nitride film 73 is a mixed film made of AlN and Hf₃N₄, it may be formed in the same manner as in the second embodiment.

After the metal nitride film 73 is formed, the gate electrode 67, the gate insulating film 66, the extension regions 65, the sidewall 68, and the source/drain regions 64 are formed by the method described in connection with the first embodiment shown in FIGS. 4 to 10, producing the structure shown in FIG. 22. After that, the interlayer insulating film 69, the contacts 70, and the wiring 71 are formed, producing the structure shown in FIG. 19.

### Fifth Embodiment

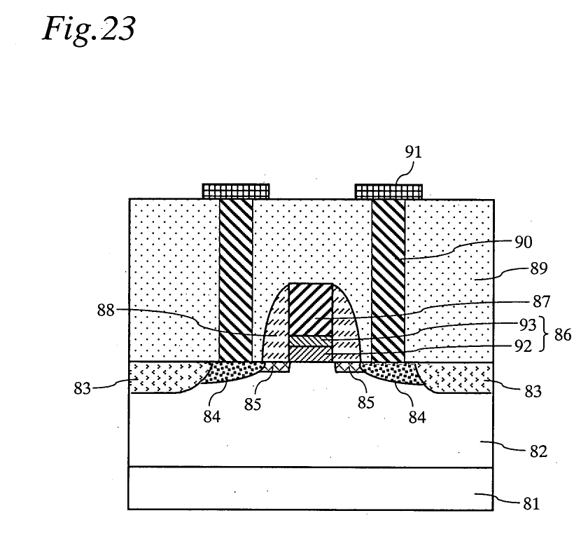

FIG. 23 is a cross-sectional view of a semiconductor device according to a fifth embodiment of the present invention.

As shown in FIG. 23, in a silicon substrate 81 are formed a diffusion layer 82, device separation regions 83, source/drain regions 84, and extension regions 85. Further, a gate insulating film 86 is formed on the silicon substrate 81, and a gate electrode 87 is formed on the gate insulating film 86. A sidewall 88 is formed on the sides of the gate insulating film 86 and the gate electrode 87. It should be noted that in FIG. 23, reference numeral 89 denotes an interlayer insulating film, 90 denotes contacts, and 91 denotes a wiring layer.

The present embodiment is characterized in that the gate insulating film 86 is made up of a silicon containing oxide film 92 and a metal oxynitride film 93 formed on the silicon containing oxide film 92.

Examples of the silicon containing oxide film 92 include: oxides formed by wet oxidation (chemical oxides); RTO (rapid thermal oxide) films formed by lamp annealing; insulating films made of H₂ (hydrogen) and O₂ (oxygen), or H₂ and N₂O (dinitrogen monoxide); and SiON (silicon oxynitride) films. An SiON film is preferably used since it has a high film density. It should be noted that the silicon containing oxide film 92 may be a multilayer film (or a film stack) made of two or more oxides, instead of a single-layer film made of a single oxide. For example, it may be a multilayer film made up of an SiON film and an SiO₂ film.

The metal oxynitride film 93 may be made of oxynitride of a single metal, or it may be a mixed film made of oxynitride of two or more metals. For example, an AlON film, an HfON film, or a mixed film made up of these films may be used as the metal oxynitride film 93.

The silicon containing oxide film of the present embodiment corresponds to the first insulating film of the third embodiment. It should, be noted that according to the third embodiment, the second insulating film (High-k film) is formed between the first insulating film and the metal oxynitride film. The present embodiment, on the other hand, is configured such that the metal oxynitride film is directly formed on the silicon containing oxide film. This arrangement allows increasing the film thickness of the silicon containing oxide film, thereby increasing the (carrier) mobility of the gate insulating film.

The silicon containing oxide film 92 preferably has a film thickness between 1.0 nm and 1.2 nm (that is, an equivalent oxide thickness between 1.0 nm and 1.2 nm). The metal oxynitride film 93, on the other hand, preferably has a film thickness between 0.3 nm and 1.0 nm (that is, an equivalent oxide thickness between 0.1 nm and 0.4 nm). It should be noted that the equivalent oxide thickness of the entire gate insulating film 86 must be set between 1.2 nm and 1.5 nm.

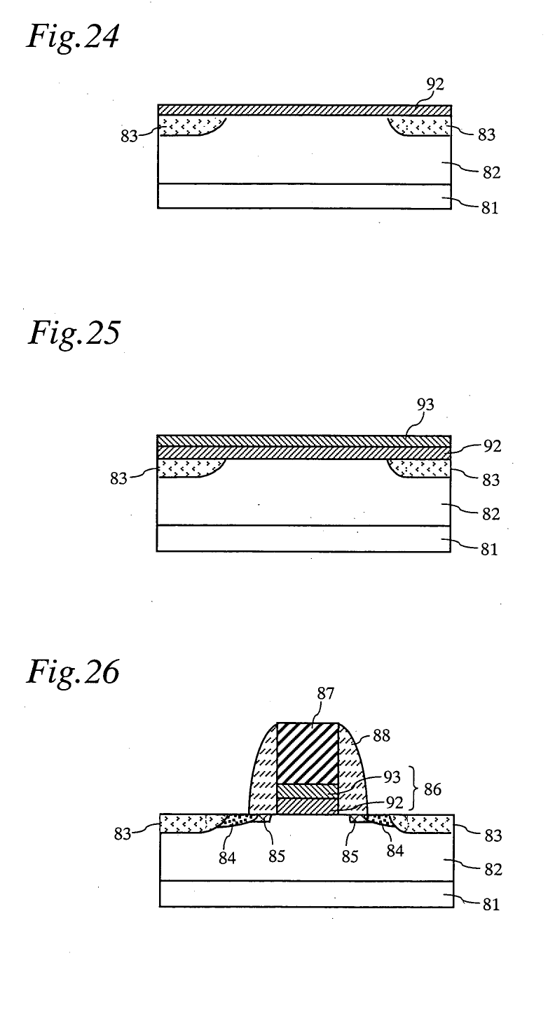

A description will be given of a method for manufacturing the semiconductor device according to the present embodiment with reference to FIGS. 24 to 26. It should be noted that in these figures, components which are the same as those in FIG. 23 will be denoted by like numerals.

First of all, the device separation regions 83 and the diffusion layer 82 are formed in the silicon substrate 81 by the method described in connection with the first embodiment shown in FIGS. 2 and 3. Then, the silicon containing oxide film 92 is formed on the silicon substrate 81, producing the structure shown in FIG. 24.

Then, the metal oxynitride film 93 is formed on the silicon containing oxide film 92, producing the structure shown in FIG. 25.

When the metal oxynitride film 93 is an AlON film, an HfON film, or a mixed film made up of these films, it may be formed in the same manner as in the third embodiment.

After the metal oxynitride film 93 is formed, the gate electrode 87, the gate insulating film 86, the extension regions 85, the sidewall 88, and the source/drain regions 84 are formed by the method described in connection with the first embodiment shown in FIGS. 4 to 10, producing the structure shown in FIG. 26. After that, the interlayer insulating film 89, the contacts 90, and the wiring 91 are formed, producing the structure shown in FIG. 23.

According to the present embodiment, the gate insulating film has a structure in which the silicon containing oxide film and the metal oxynitride film are laminated to each other. Since metal oxynitride films have a comparatively high relative permittivity, the film thickness of the gate insulating film can be reduced while reducing the gate leakage current.

The present embodiment forms the metal oxynitride film between the silicon containing oxide film and the gate electrode, which makes it possible to prevent impurities in the gate electrode from diffusing into the gate insulating film and further into the silicon substrate due to heat treatment performed after the ion implantation. Thus, degradation of the characteristics of the gate insulating film can be prevented.

Further, the present embodiment can reduce the absolute value of the PMOS threshold voltage as well as controlling the NMOS and the PMOS threshold voltages.

Still further, the present embodiment can suppress the formation of the interfacial level between the metal oxynitride film and the High-k film due to the difference between their material compositions by adjusting the ratio of the amount of oxygen to the amount of nitrogen contained in the metal oxynitride film.

According to the first to fifth embodiments, a polysilicon film is used as the gate electrode material. However, the present invention is not limited to this particular material. Any film containing silicon such as amorphous silicon and polysilicon germanium can be used as the gate electrode material. Furthermore, the present invention can be applied to gate electrodes with a multilayered structure including a polysilicon film, an amorphous silicon film, a polysilicon germanium film, or the like.

The features and advantages of the present invention may be summarized as follows.

According to the present invention described above, the metal nitride film may be formed between the second insulating film and the gate electrode, which makes it possible to prevent reaction between the second insulating film and the gate electrode. Furthermore, this arrangement can prevent impurities in the gate electrode from diffusing into the gate insulating film and further into the silicon substrate due to heat treatment performed after the ion implantation, as well as reducing the absolute value of the PMOS threshold voltage.

Further according to the present invention, the metal nitride film may be made of nitrides of two or more metals. This arrangement allows the relative permittivity of the metal nitride film to be changed by changing the mixing ratio of the metal nitrides. Therefore, it is possible to control the characteristics of the gate insulating film, such as the equivalent oxide thickness and the threshold voltage.

Still further according to the present invention, the metal oxynitride film may be formed between the second insulating film and the gate electrode, which makes it possible to prevent reaction between the second insulating film and the gate electrode. Furthermore, this arrangement can prevent impurities in the gate electrode from diffusing into the gate insulating film and further into the silicon substrate due to heat treatment performed after the ion implantation.

Still further according to the present invention, the ratio of the amount of oxygen to the amount of nitrogen contained in the metal oxynitride film may be adjusted to suppress the formation of the interfacial level between the metal oxynitride film and the second insulating film.

Still further according to the present invention, the metal nitride film may be formed on the silicon containing oxide film. This arrangement allows increasing the film thickness of the silicon containing oxide film, thereby increasing the (carrier) mobility of the gate insulating film.

Still further according to the present invention, the metal oxynitride film may be formed on the silicon containing oxide film. This arrangement also allows increasing the film thickness of the silicon containing oxide film, thereby increasing the (carrier) mobility of the gate insulating film.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2003-294264, filed on Aug. 18, 2003 including specification, claims, drawings and summary, on which the Convention priority of the present application is based, are incorporated herein by reference in its entirety.

1. A semiconductor device comprising:
a silicon substrate;
a gate insulating film on said silicon substrate; and
a gate electrode on said gate insulating film, wherein said gate insulating film includes:
a first insulating film;
a second insulating film on said first insulating film; and
a metal nitride film on said second insulating film.

2. The semiconductor device according to claim 1, wherein:
equivalent oxide thickness of said gate insulating film is between 1.2 nm and 1.5 nm;
said first insulating film is between 0.5 nm and 1.0 nm thick; and
said metal nitride film is between 0.3 nm and 1.0 nm thick.

3. The semiconductor device according to claim 1, wherein said metal nitride film is one of an AlN film and an Hf₃N₄ film.

4. The semiconductor device according to claim 1, wherein said metal nitride film includes at least two different nitrides.

5. The semiconductor device according to claim 4, wherein said metal nitride film includes a nitride of Al and a nitride of Hf.

6. The semiconductor device according to claim 1, wherein said first insulating film is includes at least one of an SiON film and an SiO₂ film.

7. The semiconductor device according to claim 1, wherein said first insulating film contains nitrogen in a concentration between 0.5 atm % and 30 atm %.

8. The semiconductor device according to claim 1, wherein said second insulating film is a high dielectric constant insulating film.

9. A semiconductor device comprising:
a silicon substrate;
a gate insulating film on said silicon substrate; and
a gate electrode on said gate insulating film, wherein said gate insulating film includes:
a first insulating film;
a second insulating film on said first insulating film; and
a metal oxynitride film on said second insulating film.

10. The semiconductor device according to claim 9, wherein said metal oxynitride film is one of an AlON film and an HfON film.

11. The semiconductor device according to claim 9, wherein said metal oxynitride film includes oxynitrides of at least two different metals.

12. The semiconductor device according to claim 11, wherein said metal oxynitride film includes oxynitrides of Al and Hf.

13. The semiconductor device according to claim 9, wherein said first insulating film is includes at least one of an SiON film and an SiO₂ film.

14. The semiconductor device according to claim 9, wherein said first insulating film contains nitrogen in a concentration between 0.5 atm % and 30 atm %.

15. The semiconductor device according to claim 9, wherein said second insulating film is a high dielectric constant insulating film.

16. The semiconductor device according to claim 15, wherein said high dielectric constant insulating film includes at least one material selected from the group consisting of MgO, Sc₂O₃, Y₂O₃, La₂O₃, Pr₂O₃, Nd₂O₃, Sm₂O₃, EuO, Gd₂O₃, Tb₂O₃, Dy₂0₃, Ho₂0₃, Er₂O₃, Tm₂O₃, Lu₂O₃, ZrO₂, HfO₂, and Al₂O₃.

17. The semiconductor device according to claim 15, wherein said high dielectric constant insulating film is a multilayer film including an SiO₂ film and a film including at least one material selected from the group consisting of MgO, Sc₂O₃, Y₂O₃, La₂O₃, Pr₂O₃, Nd₂O₃, Sm₂O₃, EuO, Gd₂O₃, Tb₂O₃, Dy₂O₃, Ho₂O₃, Er₂O₃, Tm₂O₃, Lu₂O₃, ZrO₂, HfO₂, and Al₂O₃.

18. The semiconductor device according to claim 15, wherein said high dielectric constant insulating film is at least one material mixed with SiO₂ and selected from the group consisting of MgO, Sc₂O₃, Y₂O₃, La₂O₃, Pr₂O₃, Nd₂O₃, Sm₂0₃, EuO, Gd₂O₃, Tb₂O₃, Dy₂O₃, Ho₂O₃, Er₂O₃, Tm₂O₃, Lu₂O₃, ZrO₂, HfO₂, and Al₂O₃.

19. The semiconductor device according to claim 15, wherein said high dielectric constant insulating film is a multilayer film including an SiO₂ film and a film including at least one material mixed with SiO₂, said at least one material being selected from the group consisting of MgO, Sc₂O₃, Y₂O₃, La₂O₃, Pr₂O₃, Nd₂O₃, Sm₂O₃, EuO, Gd₂O₃, Tb₂O₃, Dy₂O₃, Ho₂O₃, Er₂O₃, Tm₂O₃, Lu₂O₃, ZrO₂, HfO₂, and Al₂O₃.

20. A semiconductor device comprising:
a silicon substrate;
a gate insulating film on said silicon substrate; and
a gate electrode on said gate insulating film, wherein said gate insulating film includes:
a silicon-containing oxide film; and
a metal nitride film on said silicon-containing oxide film.

21. The semiconductor device according to claim 20, wherein said silicon-containing oxide film includes at one of an SiON film and an SiO₂ film.

22. A semiconductor device comprising:
a silicon substrate;
a gate insulating film on said silicon substrate; and
a gate electrode on said gate insulating film, wherein said gate insulating film includes:
a silicon-containing oxide film; and
a metal oxynitride film on said silicon-containing oxide film.

23. The semiconductor device according to claim 22, wherein said silicon-containing oxide film includes at least one of an SiON film and an SiO₂ film.
